(19) United States
(12) Patent Application Publication
(10) Pub. No.: US 2025/0010401 A1
(43) Pub. Date: Jan. 9, 2025

(54) LASER PROCESSING APPARATUS, LASER PROCESSING METHOD, AND METHOD OF MANUFACTURING SEMICONDUCTOR DEVICE

(71) Applicant: TOWA CORPORATION, Kyoto-shi, Kyoto (JP)

(72) Inventors: Takuya TOGAWA, Sagamihara-shi, Kanagawa (JP); Shuetsu KUDO, Sagamihara-shi, Kanagawa (JP); Shinya TAKESHIMA, Sagamihara-shi, Kanagawa (JP); Tosuki HAYASHI, Sagamihara-shi, Kanagawa (JP)

(73) Assignee: TOWA CORPORATION, Kyoto-shi, Kyoto (JP)

(21) Appl. No.: 18/708,403

(22) PCT Filed: Aug. 29, 2022
(86) PCT No.: PCT/JP2022/032396

§ 371 Date: May 8, 2024

(30) Foreign Application Priority Data
Dec. 16, 2021 (JP) 2021-204429

(51) Int. Cl. B23K 26/364; H01L 21/56; B23K 26/402

(52) U.S. Cl. CPC B23K 26/364; H01L 21/561; B23K 26/402

(57) ABSTRACT

A laser processing apparatus that removes a part of a workpiece by irradiating with laser beams, a region where portions in the workpiece different in material are provided as being aligned in a direction of scanning, and scanning the region with laser beams along the direction of scanning. A controller sets the part of the workpiece as a plurality of processing layers, and in scanning with laser beams, the controller controls an emitter and a scanner based on a processing condition for each of the plurality of processing layers. The processing condition for each of the plurality of processing layers is set based on positions of the portions in the region different in material.

### TECHNICAL FIELD

The present description relates to a laser processing apparatus, a laser processing method, and a method of manufacturing a semiconductor device.

### BACKGROUND ART

As disclosed in PTLs 1 to 3 below, a laser processing apparatus has been used in various fields. In PTL 1 (Japanese Patent Laying-Open No. 2019-063810), in irradiation of a workpiece with laser beams, a position of an imaging surface on which laser beams are focused is adjusted in accordance with a height position of a processed surface in a direction of irradiation with laser beams.

In PTL 2 (Japanese Patent Laying-Open No. 2005-342749), a workpiece is composed of a conductor layer and an insulating layer layered in a direction of irradiation with laser beams. In laser processing of this workpiece, output from a laser light source is set to be constant, and a frequency of emitted laser beams and the number of times of irradiation therewith are controlled for each layer.

What is called a non-leaded semiconductor device such as a quad flat non-leaded package (QFN) semiconductor device has been known. In the semiconductor device disclosed in PTL 3 (Japanese Patent Laying-Open No. 2011-077278), in a lead portion of a lead frame, a recess is provided in a portion opposite to a chip mount surface. In PTL 3 (paragraph [0063]), a sealing resin filled in the recess is removed by irradiating the recess with laser beams.

### CITATION LIST

### Patent Literature

PTL 1: Japanese Patent Laying-Open No. 2019-063810
PTL 2: Japanese Patent Laying-Open No. 2005-342749
PTL 3: Japanese Patent Laying-Open No. 2011-077278

### SUMMARY OF INVENTION

### Technical Problem

In a workpiece to be subjected to laser processing, portions different in material may be provided as being aligned along a “direction of scanning” with laser beams. For example, in a manufacturing method of manufacturing a QFN semiconductor device, a laser processing step of removing a part of a workpiece by irradiating with laser beams, a region where a resin material and metal are provided as being aligned along a direction of scanning with laser beams and scanning the region with laser beams along the direction of scanning may be performed.

In an example where portions different in material are provided as being aligned along the direction of scanning with laser beams, in order to obtain desired processing quality at a processed surface of a workpiece, an optimal laser processing condition different from that in an example where portions different in material are layered as being stacked in layers in a “direction of irradiation (a direction perpendicular to a processed surface)” with laser beams should be set. PTLs 1 to 3 do not particularly mention such a laser processing condition.

An object of the present specification is to disclose a laser processing apparatus and a laser processing method and a method of manufacturing a semiconductor device with the use of such a laser processing method, that allow obtainment of desired processing quality at a processed surface of a workpiece in removal of a part of the workpiece by irradiation with laser beams, of a region where portions in the workpiece different in material are provided as being aligned along a direction of scanning and scanning the region with laser beams along the direction of scanning.

### Solution to Problem

A laser processing apparatus based on the present disclosure is a laser processing apparatus that removes a part of a workpiece by irradiating with laser beams, a region where portions in the workpiece different in material are provided as being aligned along a direction of scanning and scanning the region with the laser beams along the direction of scanning. The laser processing apparatus includes an emitter that emits the laser beams, a scanner that performs a scan with the laser beams emitted from the emitter, and a controller that controls the emitter and the scanner. The controller sets the part of the workpiece as a plurality of processing layers, and in performing a scan with the laser beams, the controller controls the emitter and the scanner based on a processing condition for each of the plurality of processing layers. The processing condition for each of the plurality of processing layers is set based on positions of the portions in the region different in material.

A laser processing method based on the present disclosure is a laser processing method of removing a part of a workpiece by irradiating with laser beams, a region where portions in the workpiece different in material are provided as being aligned along a direction of scanning and scanning the region with the laser beams along the direction of scanning. The laser processing method includes emitting the laser beams from an emitter and performing a scan by a scanner with the laser beams emitted from the emitter. A controller controls the emitter and the scanner. The controller sets the part of the workpiece as a plurality of processing layers, and in performing a scan with the laser beams, the controller controls the emitter and the scanner based on a processing condition for each of the plurality of processing layers. The processing condition for each of the plurality of processing layers is set based on positions of the portions in the region different in material.

A method of manufacturing a semiconductor device based on the present disclosure includes a resin sealing step of sealing a lead frame provided with a groove portion and a semiconductor chip with a resin material with the semiconductor chip being bonded to the lead frame, removing the resin material in the groove portion by laser processing using the laser processing method based on the present disclosure, and cutting the lead frame along the groove portion.

### Advantageous Effects of Invention

According to a feature above, a laser processing apparatus and a laser processing method and a method of manufacturing a semiconductor device with the use of such a laser processing method, that allow obtainment of desired processing quality at a processed surface of a workpiece in removal of a part of the workpiece by irradiation with laser beams, of a region where portions in the workpiece different in material are provided as being aligned along a direction of scanning and scanning the region with laser beams along the direction of scanning, can be obtained.

### BRIEF DESCRIPTION OF DRAWINGS

FIG. 1 is a diagram showing a laser processing apparatus 20.

FIG. 2 is a plan view showing a construction of a lead frame 1 when viewed from a side of a rear surface 1b.

FIG. 3 is a perspective view showing a construction of a part (a lead portion 3, a tie bar 4, and a groove portion 5) of lead frame 1 when viewed from the side of rear surface 1b.

FIG. 4 is a plan view of lead frame 1 and a plurality of semiconductor chips 6 prepared in a preparation step in a method of manufacturing a semiconductor device, when viewed from a side of a front surface 1a of lead frame 1.

FIG. 5 is a cross-sectional view along the line V-V in FIG. 4 that shows a state in which semiconductor chip 6 is bonded on a die pad 2 of lead frame 1.

FIG. 6 is a cross-sectional view showing a state in which a molding step has been performed in the method of manufacturing a semiconductor device.

FIG. 7 is a cross-sectional view showing a state in which a protective film has been removed before a step of scanning with laser beams, in the method of manufacturing a semiconductor device.

FIG. 8 is a cross-sectional view showing a laser processing step in the method of manufacturing a semiconductor device.

FIG. 9 is a perspective view showing the laser processing step in the method of manufacturing a semiconductor device.

FIG. 10 is a plan view showing the laser processing step in the method of manufacturing a semiconductor device.

FIG. 11 is a perspective view showing state after the laser processing step in the method of manufacturing a semiconductor device.

FIG. 12 is a cross-sectional view showing a state after a plating step in the method of manufacturing a semiconductor device.

FIG. 13 is a cross-sectional view showing a cutting step in the method of manufacturing a semiconductor device.

FIG. 14 is a perspective view showing a semiconductor device (a semiconductor device 11) obtained by the manufacturing method in an embodiment.

FIG. 15 is a cross-sectional view showing a state of mount of the semiconductor device obtained by the manufacturing method in the embodiment.

FIG. 16 shows a table for illustrating a first embodiment of the laser processing step.

FIG. 17 shows a table for illustrating a second embodiment of the laser processing step.

FIG. 18 shows a table for illustrating a third embodiment of the laser processing step.

FIG. 19 shows a table for illustrating a fourth embodiment of the laser processing step.

FIG. 20 is a perspective view showing a state of a recess defining portion 3c obtained in the fourth embodiment of the laser processing step.

FIG. 21 is a cross-sectional view showing a state of recess defining portion 3c obtained in a modification of the fourth embodiment of the laser processing step.

### DESCRIPTION OF EMBODIMENTS

An embodiment will be described below with reference to the drawings. The same and corresponding elements in the description below have the same reference characters allotted and redundant description may not be repeated. A construction of a laser processing apparatus 20 and a lead frame 1 used in a laser processing method (or a method of manufacturing a semiconductor device) will initially be described below, and thereafter the laser processing method (or the method of manufacturing a semiconductor device) will be described.

### [Laser Processing Apparatus 20]

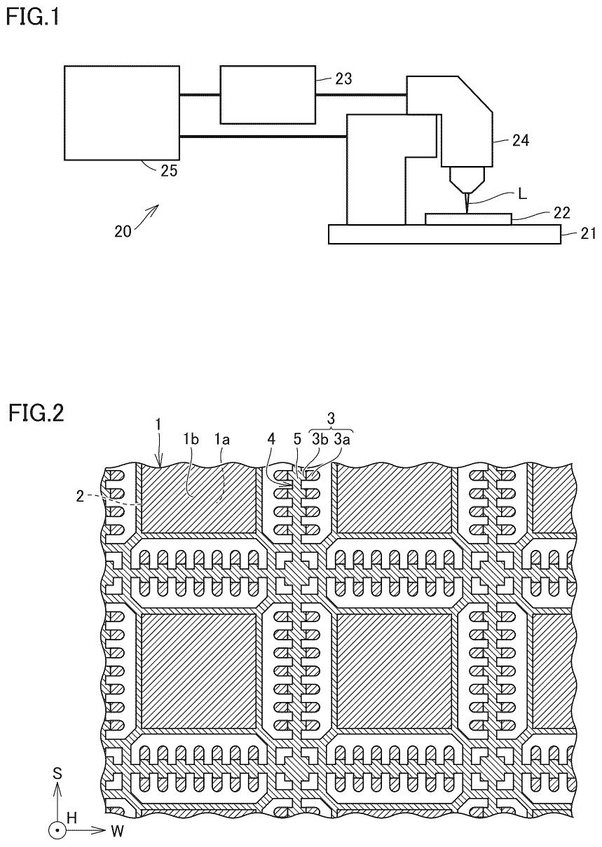

FIG. 1 is a diagram showing laser processing apparatus 20. Laser processing apparatus 20 performs laser processing treatment on a workpiece 22 held on a stage 21. Though details will be described later, in workpiece 22, portions different in material are provided as being aligned along a direction of scanning with laser beams. In other words, laser processing apparatus 20 performs the laser processing treatment on workpiece 22 in which portions different in material are provided as being aligned along the direction of scanning with laser beams.

Laser processing apparatus 20 includes an emitter 23, a scanner 24, and a controller 25. Emitter 23 generates and emits laser beams. Laser beams emitted from emitter 23 are transmitted to scanner 24 through an optical system, an optical fiber, or the like that converts a beam parameter of laser beams. Scanner 24 irradiates workpiece 22 with laser beams L, for example, with the use of a lens, a scanner mirror, and the like. Scanner 24 scans workpiece 22 with laser beams L along a prescribed direction of scanning by varying a position of workpiece 22 and a position of a beam spot of laser beams L relative to each other. A part of workpiece 22 is thus removed (cut).

Controller 25 controls emitter 23 and scanner 24. Controller 25 sets a part of workpiece 22 (that is, a part of workpiece 22 to be removed by laser processing) as a plurality of processing layers, and in scanning with laser beams, controller 25 controls emitter 23 and scanner 24 based on a processing condition (what is called a processing recipe) for each of the plurality of processing layers.

The processing condition can include output energy of laser beams, a pulse frequency of laser beams, a speed of scanning with laser beams, a pitch of scanning with laser beams, a spot diameter on a processed surface to be processed by laser beams, a spot shape on the processed surface to be processed by laser beams, a trace of scanning with laser beams, the number of times of scanning with laser beams, and ON/OFF timing (duty ratio) of laser beams.

Geometric data is generated, for example, with the use of a computer aided design (CAD) apparatus. For example, a computer aided manufacturing (CAM) apparatus generates and stores processing data (combination of the geometric data and the processing condition) for processing of workpiece 22 by laser processing apparatus 20 based on geometric data inputted from the CAD apparatus or geometric data it directly edits. The CAM apparatus further generates a program (for example, an NC code or a sequence treatment code) in a determined order. The processing condition in a layer processing method based on the present disclosure can be designated as set forth above. Controller 25 controls emitter 23 and scanner 24 in synchronization and in coordination based on the thus designated processing condition for each of a plurality of processing layers.

### [Lead Frame 1]

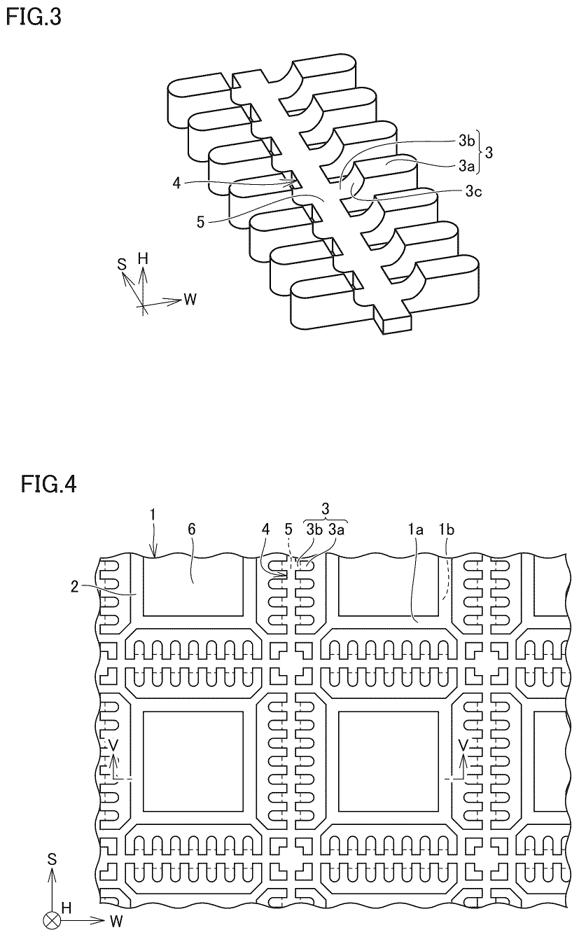

Workpiece 22 (FIG. 1) can include as a constituent element thereof, lead frame 1 shown below. FIG. 2 is a plan view showing a construction of lead frame 1 when viewed from a side of a rear surface 1b and FIG. 3 is a perspective view showing a construction of a part (a lead portion 3, a tie bar 4, and a groove portion 5) of lead frame 1 when viewed from the side of rear surface 1b.

Though FIG. 2 does not show a cross-sectional construction of lead frame 1, a diagonally extending hatching is provided to a portion that forms lead frame 1 for the sake of convenience of illustration. Two types of hatching are used, and a difference therebetween will be described later. FIGS. 2 and 3 show a length direction S, a width direction W, and a height direction H for the sake of convenience of description, and these directions are referred to as appropriate in the description below. These directions are illustrated as appropriate similarly also in FIG. 4 and following figures.

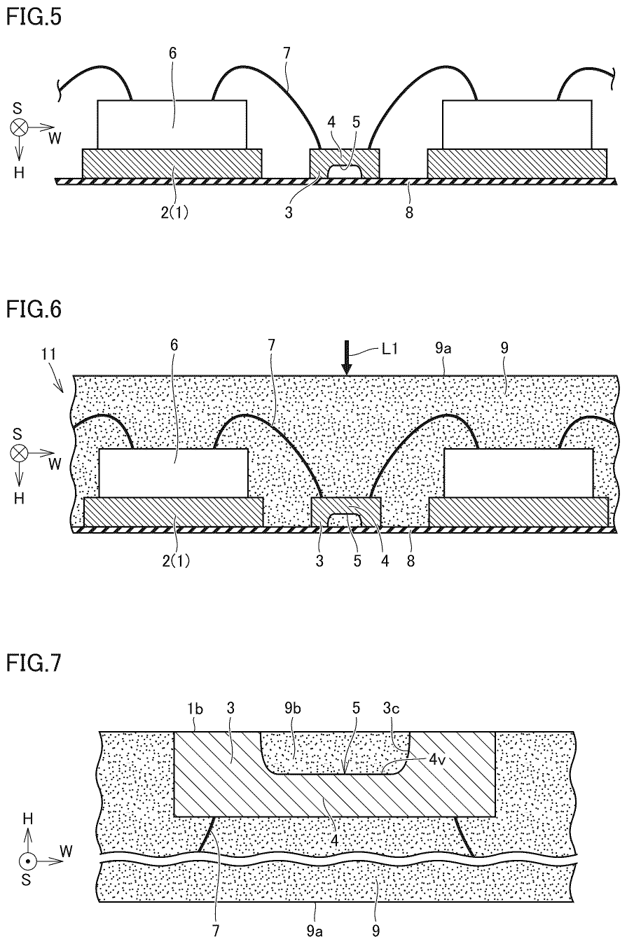

As shown in FIG. 2, lead frame 1 is substantially in a shape of a plate that extends along both of length direction S and width direction W. Lead frame 1 is provided with a front surface 1a located on a side where a semiconductor chip 6 (FIGS. 4 and 5) is mounted and a rear surface 1b located opposite to front surface 1a, and it is composed of metal such as copper. Lead frame 1 includes a plurality of die pads 2, a plurality of lead portions 3 (FIG. 3), and a plurality of tie bars 4 (FIG. 3).

### (Die Pad 2, Lead Portion 3, and Tie Bar 4).

The plurality of die pads 2 are disposed at a distance in both of length direction S and width direction W. Die pad 2 is a portion where semiconductor chip 6 is mounted on front surface 1a thereof (see FIG. 5). As shown in FIG. 2, a plurality of lead portions 3 are arranged as being aligned in a rectangular shape around (on four sides of) each of the plurality of die pads 2. Each of the plurality of lead portions 3 includes a large-thickness portion 3a and a small-thickness portion 3b (FIGS. 3 and 4).

A recess defining portion 3c (FIG. 3) is provided in a portion between large-thickness portion 3a and small-thickness portion 3b in a surface of lead portion 3. In mounting of a semiconductor device on a printed board, a land 13 (FIG. 15) of the printed board and lead portion 3 are connected to each other through solder 14. At this time, as solder 14 (see FIG. 15) is accumulated in the inside (recess) of recess defining portion 3c, wettability of solder 14 can be improved and a better soldered structure can be obtained.

Referring again to FIG. 2, a plurality of tie bars 4 are arranged in grids to surround each of the plurality of die pads 2. A plurality of lead portions 3 are provided on opposing sides of a single tie bar 4, and the plurality of lead portions 3 are aligned at a distance along a direction of extension of tie bar 4. In lead portion 3, large-thickness portion 3a is coupled to tie bar 4 with small-thickness portion 3b being interposed. In height direction H, die pad 2 and large-thickness portion 3a are larger in height dimension (that is, thickness) than small-thickness portion 3b.

Die pad 2 and large-thickness portion 3a are provided with a hatching that extends from an upper right side toward a lower left side of the sheet plane of FIG. 2. Small-thickness portion 3b of lead portion 3 and tie bar 4 are provided with a hatching that extends from an upper left side toward a lower right side of the sheet plane of FIG. 2.

### (Groove Portion 5)

Referring to FIG. 3, with attention being paid to surfaces of tie bar 4 and large-thickness portion 3a and small-thickness portion 3b of lead portion 3 that are located on a “negative side in height direction H” shown in FIG. 3, height positions of these surfaces are the same. With attention being paid to surfaces located on a “positive side in height direction H” shown in FIG. 3, on the other hand, the height position of the surface of large-thickness portion 3a of lead portion 3 is higher than the height position of the surface of tie bar 4 and the height position of the surface of small-thickness portion 3b of lead portion 3.

In other words, the surface on the positive side of tie bar 4 and the surface on the positive side of small-thickness portion 3b of lead portion 3 exhibit a shape recessed relative to the surface on the positive side of large-thickness portion 3a of lead portion 3. With this structure, in lead frame 1, groove portions 5 in grids that extend along each of height direction H and width direction W are provided on the side of rear surface 1b (FIG. 2) of tie bar 4.

Groove portion 5 does not pass through lead frame 1 in height direction H but has a groove depth, for example, half lead frame 1 (large-thickness portion 3a), and it can be provided by etching (wet etching) of lead frame 1. A groove width is, for example, from 0.40 mm to 0.50 mm. The groove width and the groove depth should only be set in consideration of strength secured to such an extent as not causing a defect such as deformation in a post process, a visual inspection well conducted in a post process, good strength of mounting of a semiconductor device which is a finished product, or the like.

### [Method of Manufacturing Semiconductor Device]

FIG. 4 is a plan view of lead frame 1 and a plurality of semiconductor chips 6 prepared in a preparation step in a method of manufacturing a semiconductor device, when viewed from a side of front surface 1a of lead frame 1. FIG. 5 is a cross-sectional view along the line V-V in FIG. 4 that shows a state in which semiconductor chip 6 is bonded on die pad 2 of lead frame 1.

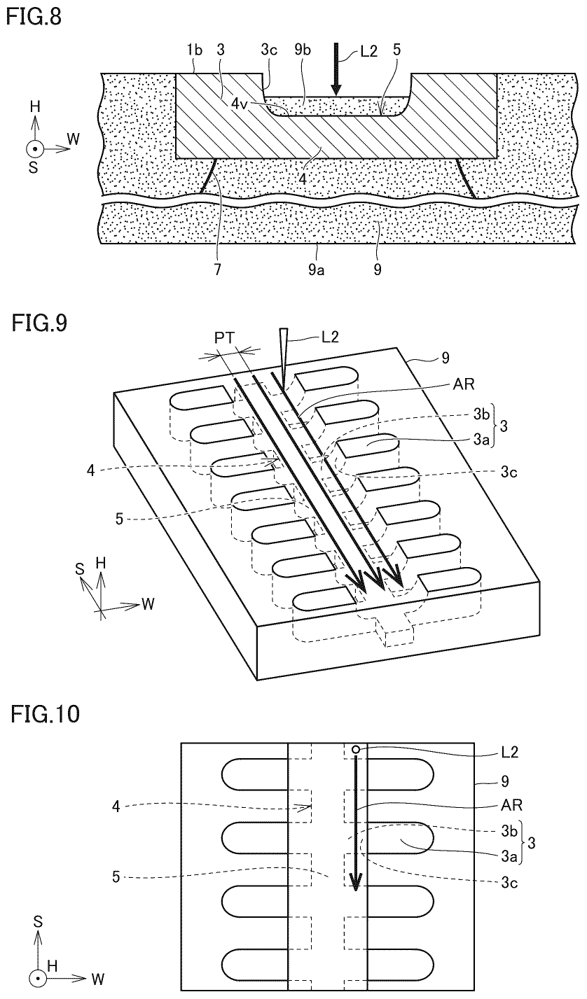

The method of manufacturing a semiconductor device includes a preparation step, a molding step, a laser processing step, a plating step, and a cutting step. Though details will be described later, in the molding step, lead frame 1 and a plurality of semiconductor chips 6 mounted on lead frame 1 are sealed with a resin material 9 (see FIG. 6) to form a resin molded product 11 (FIG. 6). In the laser processing step, resin material 9 in groove portion 5 is removed by scanning over groove portion 5 in resin molded product 11 with laser beams L2 (FIG. 8) along length direction S.

In the method of manufacturing a semiconductor device in the embodiment, the cutting step (see FIG. 13) is further performed. In the cutting step, a blade 12 is used to cut a total thickness portion of lead frame 1 and resin material 9. Cutting of resin molded product 11 along groove portion 5 provides an individualized unit resin molded product (semiconductor device 11). Each step will be described below in detail.

### (Preparation Step)

As shown in FIGS. 4 and 5, a plurality of electrodes provided in each semiconductor chip 6 are electrically connected to lead portion 3 (large-thickness portion 3a) through a bonding wire 7. FIG. 4 does not show bonding wire 7 for the sake of convenience.

### (Molding Step)

FIG. 6 is a cross-sectional view showing a state in which the molding step has been performed. In the molding step, with semiconductor chip 6 being bonded, lead frame 1 and semiconductor chip 6 are sealed with resin material 9. Resin molded product 11 is thus obtained. As shown in FIGS. 5 and 6, desirably, before the molding step, a protective film 8 (for example, a polyimide resin tape) is bonded to a side of groove portion 5 in lead frame 1, and after protective film 8 is bonded, resin sealing is performed.

The method of manufacturing a semiconductor device may further include a step of laser marking by irradiation of a front surface 9a (FIG. 6) of resin molded product 11 opposite to groove portion 5 in lead frame 1 with laser beams L1, between the molding step and the laser processing step which will be described next. Any information such as a model number or a serial number can be printed by scanning with pulsed laser beams with the use of a scanning optical system.

As shown in FIG. 7, protective film 8 is peeled off from lead frame 1 before the laser processing step which will be described next. As a result of removal of protective film 8, resin material 9 (9b) formed in groove portion 5 in lead frame 1 is exposed. Protective film 8 may be peeled off from lead frame 1 before the step of laser marking described with reference to FIG. 6.

### (Laser Processing Step)

FIGS. 8 to 10 are a cross-sectional view, a perspective view, and a plan view showing the laser processing step, respectively. In the laser processing step, it is performed while a region in resin molded product 11 (workpiece) where portions different in material are provided as being aligned along the direction of scanning with laser beams is irradiated with laser beams L2.

Resin material 9 (9b) in groove portion 5 is irradiated with laser beams L2 and scanned therewith along a direction of scanning AR. A surface portion in the inside of groove portion 5 is formed of the resin material. In an intermediate portion (a lower side of the surface portion) in the inside of groove portion 5, on the other hand, portions different in material, that is, resin material 9 and small-thickness portion 3b or resin material 9 and recess defining portion 3c, are provided as being aligned along direction of scanning AR with laser beams L2. This region is irradiated with laser beams L2. In this region, lead portion 3 (small-thickness portion 3b and recess defining portion 3c) is made of metal. In an example where materials common as metal and resin are adopted, resin material 9 is more likely to be processed with laser beams but lead portion 3 is less likely to be processed with laser beams. In other words, resin material 9 and lead portion 3 are significantly different from each other in rate of processing (details of which will be described later). Scanning with laser beams L2 is performed a plurality of times, with laser beams being shifted in a width direction at a scanning pitch PT.

In the laser processing step, controller 25 (FIG. 1) sets a part (that is, resin material 9 (9b) in groove portion 5) of resin molded product 11 (workpiece) as a plurality of processing layers, and in performing a scan with laser beams, controller 25 controls emitter 23 and scanner 24 based on a processing condition for each of the plurality of processing layers. Further details about the processing condition in the laser processing step will be described later.

Laser light L2 could be provided by pulsed laser such as YAG laser or YVO4 laser emitted from a lasing device, green laser in which the wavelength of the laser light emitted therefrom is converted by a second harmonic generation (SHG) material, or ultraviolet laser obtained by wavelength conversion of the laser beams by a third harmonic generation (THG) material. In connection with a pulse width, laser having a frequency of a nanosecond or picosecond is available. Controller 25 (FIG. 1) controls emitter 23 and scanner 24 to vary the condition of processing by laser beams L2. A wavelength, output, a diameter of concentration, an irradiation time period, or the like of laser beams L2 is optimized so as to efficiently remove resin material 9 (9b), depending on a material for resin material 9 (9b) or a size of resin material 9 (9b) (the groove width of groove portion 5 or the like).

### (Plating Step)

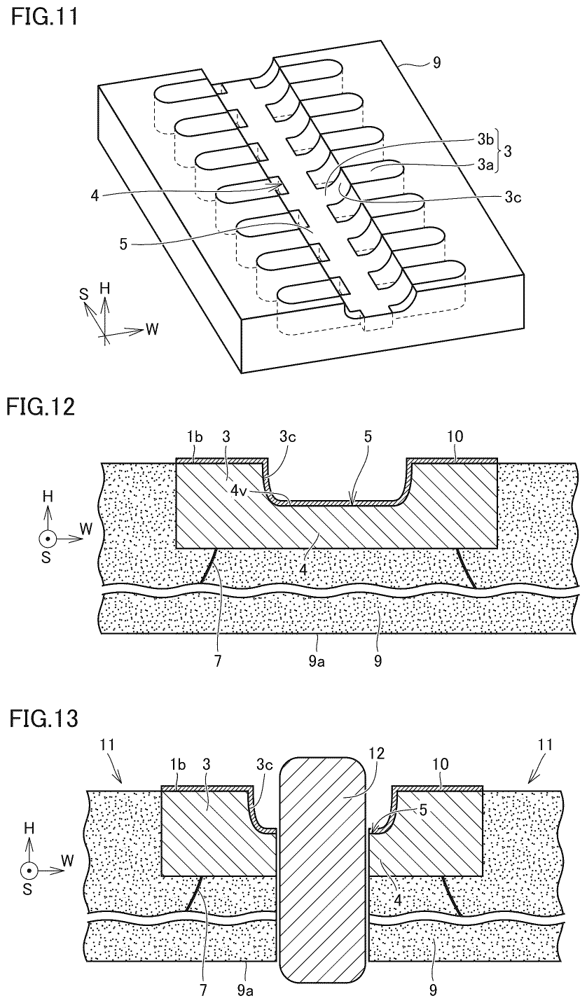

FIG. 11 is a perspective view showing state after the laser processing step. FIG. 12 is a cross-sectional view showing a state after the plating step. As shown in FIG. 11, as a result of the laser processing step, the resin material in groove portion 5 has been removed and a surface of tie bar 4, a surface of small-thickness portion 3b, and a surface of recess defining portion 3c are exposed. Groove portion 5 is revealed.

As shown in FIG. 12, after the resin material in groove portion 5 is removed, lead frame 1 is subjected to plating treatment. A plated layer 10 is formed on a surface of die pad 2 of lead frame 1, a front surface 4v of tie bar 4 of lead frame 1, the surface of small-thickness portion 3b of lead portion 3, and recess defining portion 3c. A material having good solderability can be selected as a material for plated layer 10, depending on a solder material to be used for mounting. For example, when solder based on tin (Sn) is employed, tin (Sn), a tin-copper alloy (Sn—Cu), a tin-silver alloy (Sn—Ag), tin-bismuth (Sn—Bi), or the like can be employed, or plated layer 10 made of a multilayer body containing Ni for primary plating on a side of lead frame 1 can also be provided.

In the plating step, desirably, lead frame 1 is subjected to prescribed cleaning treatment and thereafter to the plating treatment. In addition to the cleaning treatment, removal of an oxide film or treatment for surface activation or the like may be performed as surface treatment of lead frame 1 as pretreatment for the plating step. Resin material 9 in groove portion 5 may have been reformed (for example, carbonized) by irradiation with laser beams. Even when resin material 9 slightly remains, reformed resin material 9 can be removed from the inside of groove portion 5 by such surface treatment as the cleaning treatment before the plating treatment.

### (Cutting Step)

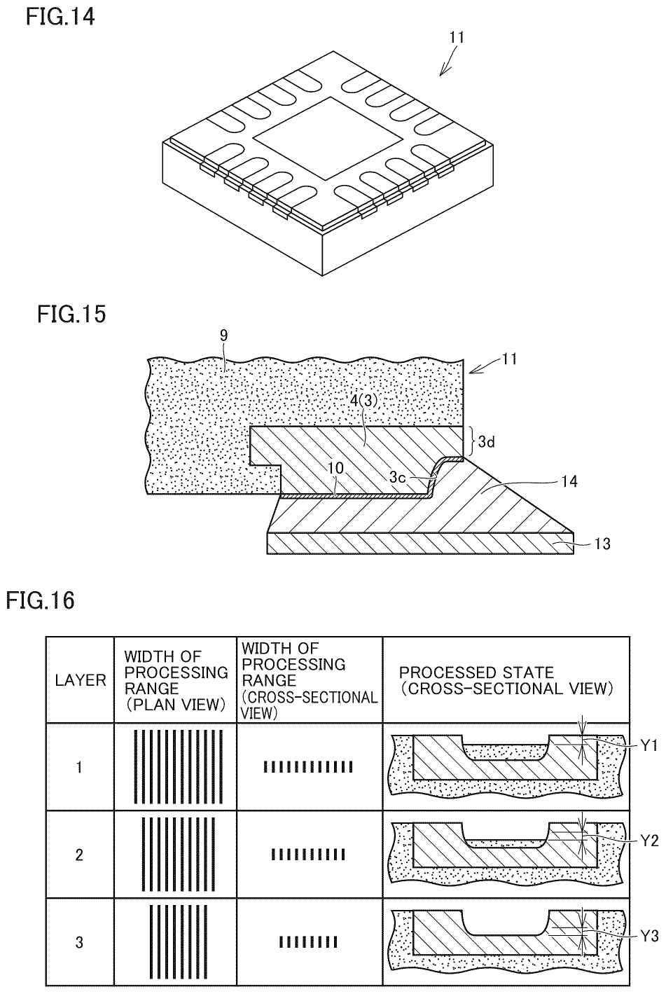

As shown in FIG. 13, lead frame 1 subjected to the plating treatment is cut along groove portion 5. In this cutting step, blade 12 is used to cut the total thickness portion of lead frame 1 and resin material 9. By performing the cutting step, semiconductor devices 11 as a plurality of unit resin molded products are obtained. As shown in FIG. 14, semiconductor device 11 is a QFN non-leaded product from which an electrical connection lead does not protrude to the outside thereof in a plan view.

As shown in FIG. 15, in semiconductor device 11, a step is provided in a side portion (piece portion) of each lead portion 3, and original metal is exposed at a side surface 3d of lead portion 3 without plated layer 10 being formed. Semiconductor device 11 is mounted on a printed board, for example, with the side of resin material 9 facing up and the side of lead portion 3 facing down. The printed board is provided with land 13 at a position corresponding to lead portion 3, and lead portion 3 and land 13 are connected to each other through solder 14. At this time, solder 14 is accumulated in the inside (recess) of recess defining portion 3c, to thereby improve wettability of solder 14 and to obtain a better soldered structure.

### [Processing Condition in Laser Processing Step]

The processing condition for laser processing applicable to the method of manufacturing a semiconductor device described above will be described below with reference to FIGS. 16 to 21. Contents below are applicable also to any laser processing method without being limited to the method of manufacturing a semiconductor device.

As described above, laser processing apparatus 20 (FIG. 1) performs the laser processing treatment on the resin molded product shown in FIGS. 8 to 10. The workpiece is lead frame 1 provided with groove portion 5 and semiconductor chip 6 that are sealed with resin material 9 with semiconductor chip 6 being bonded to lead frame 1. A part of the workpiece refers to resin material 9 provided to bury groove portion 5.

In such a workpiece (resin molded product), portions different in material are provided as being aligned along direction of scanning AR (FIG. 9) with laser beams. In the laser processing step, the resin molded product (workpiece) including a region where portions different in material are provided as being aligned along direction of scanning AR with laser beams is subjected to the laser processing treatment while the region is irradiated with laser beams L2. Resin material 9 in groove portion 5 is removed by irradiation of resin material 9 in groove portion 5 with laser beams L2 and scanning of the resin material with laser beams L2 in direction of scanning AR.

The part of the workpiece (the portion to be removed by laser processing, resin material 9 present in the inside of groove portion 5 here) is set in advance as a plurality of processing layers, and in scanning with laser beams, controller 25 controls emitter 23 and scanner 24 based on a processing condition for each of the plurality of processing layers. The processing condition for each of the plurality of processing layers is set based on positions of the portions different in material in the region (the region where the portions different in material are provided as being aligned along direction of scanning AR with laser beams).

For example, setting is made such that when processing conditions for any two processing layers of the plurality of processing layers are compared with each other, a value of at least one of energy of laser beams, a pulse frequency of laser beams, a speed of scanning with laser beams, and a pitch of scanning with laser beams is different (based on the positions of the portions different in material in the region). In addition, the number of times of scanning is set as the processing condition for each layer. The number of times of scanning may also be set to be different between the processing conditions for any two processing layers of the plurality of processing layers when they are compared with each other. A condition under which a rate of processing in height direction H indicating a depth is high includes, for example, high energy, a high pulse frequency, a low speed of scanning, and a narrow pitch of scanning. For example, when energy of laser beams is lowered even when the scanning speed is lowered, the overall rate of processing can be lowered, and the rate of processing or accuracy in position of processing can be set by comprehensively taking into account various processing conditions including them.

In the method of manufacturing a semiconductor device, in the region of the workpiece, the resin material (resin material 9) and metal (surface of each of small-thickness portion 3b and recess defining portion 3c) are provided as being aligned along direction of scanning AR, and the processing condition for each of the plurality of processing layers is set based on positions of the resin material and the metal in this region. Exemplary processing conditions for each of the plurality of processing layers can include examples shown in FIGS. 16 to 19. First to fourth embodiments shown below can be carried out alone or in combination.

### First Embodiment

FIG. 16 shows a table for illustrating a first embodiment of the laser processing step. In the first embodiment, with a dimension in a direction orthogonal to both of a direction of irradiation and the direction of scanning with laser beams being defined as a width, when the processing conditions for any two processing layers of the plurality of processing layers are compared with each other, a difference resides in a width of a range of irradiation with laser beams.

Specifically, processing is performed in the order of a layer 1, a layer 2, and a layer 3. In layer 1, a range from a surface portion to a depth Y1 is subjected to the laser processing. At this time, a width of a processing range is brought in correspondence, for example, with a groove width in the range from the surface portion to depth Y1.

In layer 2, a range from depth Y1 to a depth Y2 is subjected to the laser processing. At this time, the width of the processing range is brought in correspondence, for example, with the groove width in the range from depth Y1 to depth Y2. The processing range in layer 2 is narrower in width than the processing range in layer 1. Similarly, in layer 3, a range from depth Y2 to a depth Y3 is subjected to the laser processing. At this time, the width of the processing range is brought in correspondence, for example, with the groove width in the range from depth Y2 to depth Y3. The processing range in layer 3 is narrower in width than the processing range in layer 2.

In other words, at least the processing condition “the width of the processing range” as the processing condition for each of the plurality of processing layers is different between the region where the resin material (resin material 9) and metal (surface of each of small-thickness portion 3b and recess defining portion 3c) are provided as being aligned along direction of scanning AR and a region otherwise, and particularly here, the processing condition is set in accordance with a profile of an inner surface of groove portion 5.

Specifically, the width of the processing range is set to decrease in the order of layers 1 to 3. The processing condition for each of the plurality of processing layers is set in accordance with cross-section profiles of the portions different in material in the workpiece. According to this construction, excessive cutting of small-thickness portion 3b and recess defining portion 3c in lead portion 3 or excessive cutting of the surface of resin material 9 adjacent to those portions in length direction S (direction of scanning) can be suppressed.

By finely adjusting the processing condition for each layer, surface roughness or precision is set to a desired state, occurrence of burr or chipping can also be suppressed, and furthermore, rough processing and fine-tune processing can also be achieved in a shorter period of time.

In addition, for example, based on the processing condition as above, a processed surface of the workpiece can be adjusted to a desired shape or desired quality, and the surfaces of small-thickness portion 3b and recess defining portion 3c in lead portion 3 and the surface of resin material 9 adjacent in length direction S (direction of scanning) can also be set to be flush or substantially flush. The processing condition for obtaining such functions and effects can contemplate improvement in quality in the region (the region where the portions different in material are provided as being aligned along direction of scanning AR with laser beams) and can be concluded as being set based on the positions of the portions different in material in the region.

### Second Embodiment

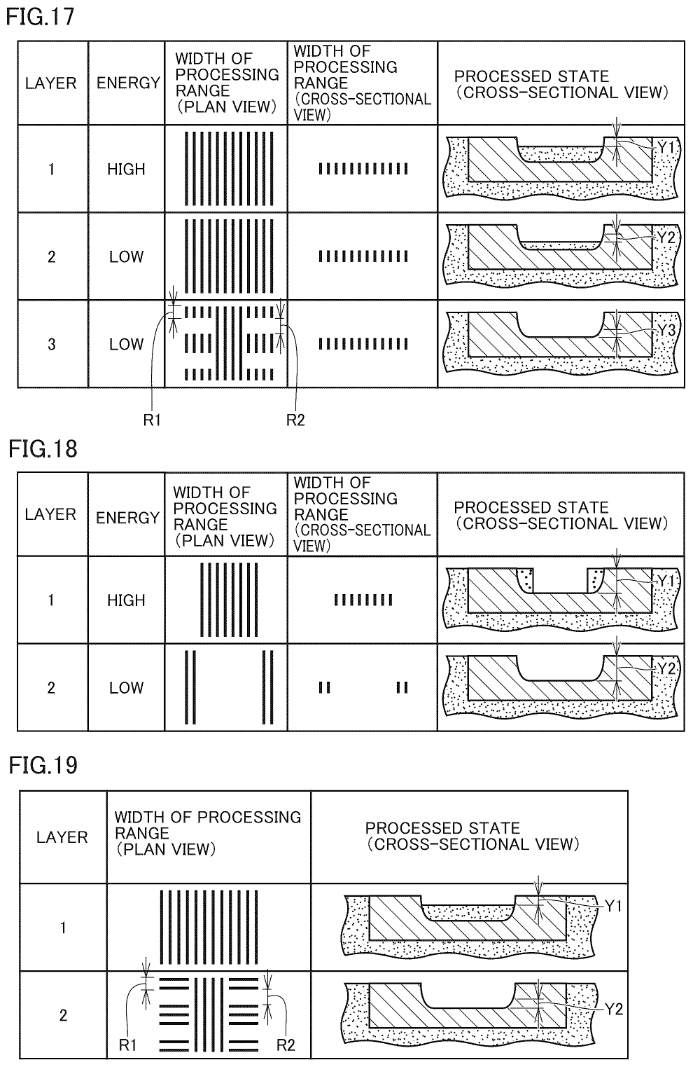

FIG. 17 shows a table for illustrating a second embodiment of the laser processing step. In the case of the second embodiment, layers 1 and 2 are identical to each other in width of the processing range, whereas layer 1 is higher and layer 2 is lower in energy of laser beams. Furthermore, in layer 3, the length of the processing range (the length of the processing range in the direction of scanning) is varied.

Specifically, in connection with the processing condition for any one processing layer (layer 3 here) of the plurality of processing layers, when a first range R1 and a second range R2 aligned in the direction of scanning and irradiated with laser beams are compared with each other, a value of at least one of energy of laser beams, a pulse frequency of laser beams, a speed of scanning with laser beams, and a pitch of scanning with laser beams is different therebetween.

In first range R1 in layer 3, all regions in the width direction are irradiated with laser beams. In second range R2 in layer 3, on the other hand, only a central region in the width direction is irradiated with laser beams. First range R1 corresponds to a region, for example, provided with lead portion 3, and it is subjected to cutting toward the surface of small-thickness portion 3b and the surface of recess defining portion 3c. Second range R2 corresponds to a region, for example, not provided with lead portion 3. Resin material 9 between lead portions 3 and 3 adjacent in the direction of scanning is not subjected to cutting or is subjected to cutting to a lesser extent. The processing condition is different between the region where the resin material (resin material 9) and metal (surface of each of small-thickness portion 3b and recess defining portion 3c) are provided as being aligned along direction of scanning AR and a region otherwise. According to such a feature as well, for example, the surfaces of small-thickness portion 3b and recess defining portion 3c in lead portion 3 and the surface of resin material 9 adjacent in length direction S (direction of scanning) can be set to be flush or substantially flush. The processing condition for obtaining such functions and effects can also contemplate improvement in quality in the region (the region where the portions different in material are provided as being aligned along direction of scanning AR with laser beams) and can be concluded as being set based on the positions of the portions different in material in the region.

### Third Embodiment

FIG. 18 shows a table for illustrating a third embodiment of the laser processing step. In the first and second embodiments described above, layers 1 to 3 are set as being stacked in the direction of irradiation with laser beams. In the case of the third embodiment shown in FIG. 18, on the other hand, heights of the processing ranges in layers 1 and 2 are set as being substantially equal, whereas positions in the width direction of the processing ranges are different from each other.

Laser processing in a first stage is performed in accordance with contents set as the processing condition for a layer Y1, and laser processing in a second stage is performed in accordance with contents set as the processing condition for a layer Y2. In the first stage, the resin material is removed only from a portion close to the center in the width direction, and in the second stage, the resin material is removed only from portions close to opposing ends in the width direction. As shown in FIG. 18, energy of laser beams may be lower in the second stage than in the first stage.

The processing condition is different between the region where the resin material (resin material 9) and metal (surface of each of small-thickness portion 3b and recess defining portion 3c) are provided as being aligned along direction of scanning AR and a region otherwise. For example, by decreasing an amount of heat supplied to the portions close to the opposing ends in the width direction, thermal influence on semiconductor chip 6 can also be lessened.

According to such a feature as well, the surfaces of small-thickness portion 3b and recess defining portion 3c in lead portion 3 and the surface of resin material 9 adjacent in length direction S (direction of scanning) can be set to be flush or substantially flush. The processing condition for obtaining such functions and effects can also contemplate improvement in quality in the region (the region where the portions different in material are provided as being aligned along direction of scanning AR with laser beams) and can be concluded as being set based on the positions of the portions different in material in the region.

### Fourth Embodiment

FIG. 19 shows a table for illustrating a fourth embodiment of the laser processing step. In the fourth embodiment as well, in connection with the processing condition for any one processing layer (layer 2 here) of the plurality of processing layers, when first range R1 and second range R2 aligned in the direction of scanning and irradiated with laser beams are compared with each other, a value of at least one of energy of laser beams, a pulse frequency of laser beams, a speed of scanning with laser beams, and a pitch of scanning with laser beams is different therebetween. The processing condition is different between the region where the resin material (resin material 9) and metal (surface of each of small-thickness portion 3b and recess defining portion 3c) are provided as being aligned along direction of scanning AR and a region otherwise.

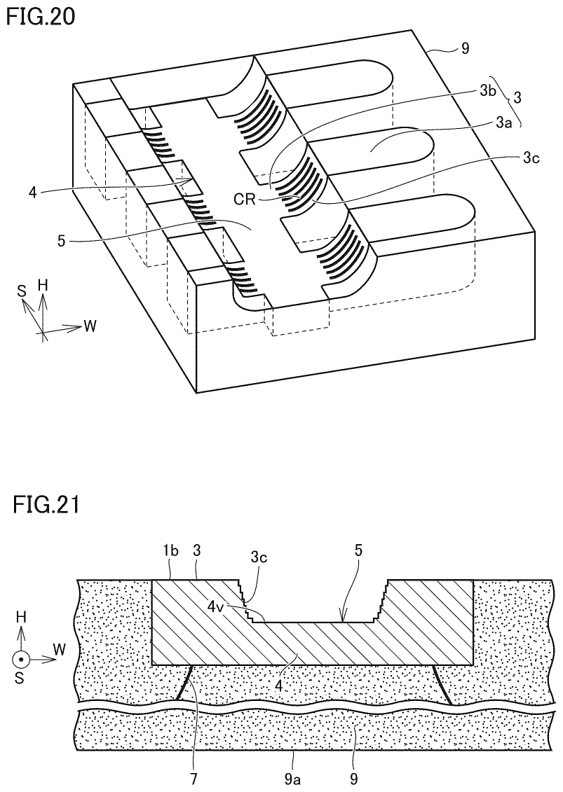

In the fourth embodiment, the opposing ends in the width direction of first range R1 in layer Y2 are scanned with laser beams in the width direction. As shown in FIG. 20, according to this feature, for example, a surface profile of recess defining portion 3c of lead portion 3 can positively be altered to have irregularities CR, for example, to thereby adjust solderability in recess defining portion 3c of lead portion 3 to desired solderability. Irregularities CR as the surface profile can maintain surface roughness even after plated layer 10 is formed in the plating step, and they can be provided under a processing condition suitable for prevention of solder defects with fluidity and adhesiveness, that is, wettability, of solder being improved.

Referring to FIG. 21, in a modification of the fourth embodiment (FIGS. 19 and 20), the opposing ends in the width direction of first range R1 in layer Y2 may be scanned with laser beams in the length direction. According to this feature, the irregularities can be provided in the surface of recess defining portion 3c of lead portion 3, for example, to thereby adjust solderability in recess defining portion 3c of lead portion 3 to desired solderability.

According to the feature as described above as well, the surfaces of small-thickness portion 3b and recess defining portion 3c in lead portion 3 and the surface of resin material 9 adjacent in length direction S (direction of scanning) can be set to be flush or substantially flush. The processing condition for obtaining such functions and effects can also contemplate improvement in quality in the region (the region where the portions different in material are provided as being aligned along direction of scanning AR with laser beams) and can be concluded as being set based on the positions of the portions different in material in the region.

Though embodiments have been described above, contents disclosed above are illustrative and non-restrictive in every respect. The technical scope of the present invention is defined by the terms of the claims and is intended to include any modifications within the scope and meaning equivalent to the terms of the claims.

### REFERENCE SIGNS LIST

1 lead frame; 1a, 4v, 9a front surface; 1b rear surface; 2 die pad; 3 lead portion; 3a large-thickness portion; 3b small-thickness portion; 3c recess defining portion; 3d side surface; 4 tie bar; 5 groove portion; 6 semiconductor chip; 7 bonding wire; 8 protective film; 9 resin material; 10 plated layer; 11 resin molded product (semiconductor device); 12 blade; 13 land; 14 solder; 20 laser processing apparatus; 21 stage; 22 workpiece; 23 emitter; 24 scanner; 25 controller; AR direction of scanning; H height direction; L, L1, L2 laser beams; R1 first range; R2 second range; S length direction; W width direction.

1. A laser processing apparatus that removes a part of a workpiece by irradiating with laser beams, a region where portions in the workpiece different in material are provided as being aligned along a direction of scanning and scanning the region with the laser beams along the direction of scanning, the laser processing apparatus comprising:
an emitter that emits the laser beams;
a scanner that performs a scan with the laser beams emitted from the emitter; and
a controller that controls the emitter and the scanner, wherein
the controller sets the part of the workpiece as a plurality of processing layers, and in performing a scan with the laser beams, the controller controls the emitter and the scanner based on a processing condition for each of the plurality of processing layers, and
the processing condition for each of the plurality of processing layers is set based on positions of the portions in the region different in material.

2. The laser processing apparatus according to claim 1, wherein
in the region in the workpiece, a resin material and metal are provided as being aligned along the direction of scanning, and
the processing condition for each of the plurality of processing layers is set based on positions of the resin material and the metal in the region.

3. The laser processing apparatus according to claim 2, wherein
the workpiece is a lead frame provided with a groove portion and a semiconductor chip that are sealed with the resin material with the semiconductor chip being bonded to the lead frame,
the part of the workpiece is the resin material provided to bury the groove portion, and
the resin material in the groove portion is removed by irradiating the resin material in the groove portion with the laser beams and scanning the resin material with the laser beams in the direction of scanning.

4. The laser processing apparatus according to claim 3, wherein
the processing condition for each of the plurality of processing layers is set in accordance with a profile of an inner surface of the groove portion.

5. The laser processing apparatus according to claim 1, wherein
when processing conditions for any two processing layers of the plurality of processing layers are compared with each other, a value of at least one of energy of the laser beams, a pulse frequency of the laser beams, a speed of scanning with the laser beams, and a pitch of scanning with the laser beams is different.

6. The laser processing apparatus according to claim 1, wherein
when processing conditions for any two processing layers of the plurality of processing layers are compared with each other, a width of a range irradiated with the laser beams is different between the any two processing layers, with a dimension in a direction orthogonal to both of a direction of irradiation and the direction of scanning with the laser beams being defined as the width.

7. The laser processing apparatus according to claim 1, wherein
in connection with the processing condition for any one processing layer of the plurality of processing layers, when a first range and a second range aligned in the direction of scanning and irradiated with the laser beams are compared with each other, a value of at least one of energy of the laser beams, a pulse frequency of the laser beams, a speed of scanning with the laser beams, and a pitch of scanning with the laser beams is different between the first range and the second range.

8. The laser processing apparatus according to claim 1, wherein
the processing condition for each of the plurality of processing layers is set in accordance with a cross-section profile of a portion in the workpiece different in material.

9. A laser processing method of removing a part of a workpiece by irradiating with laser beams, a region where portions in the workpiece different in material are provided as being aligned along a direction of scanning and scanning the region with the laser beams along the direction of scanning, the laser processing method comprising:
emitting the laser beams from an emitter; and
performing a scan by a scanner with the laser beams emitted from the emitter, wherein
a controller controls the emitter and the scanner,
the controller sets the part of the workpiece as a plurality of processing layers, and in performing a scan with the laser beams, the controller controls the emitter and the scanner based on a processing condition for each of the plurality of processing layers, and
the processing condition for each of the plurality of processing layers is set based on positions of the portions in the region different in material.

10. A method of manufacturing a semiconductor device, the method comprising:
sealing a lead frame provided with a groove portion and a semiconductor chip with a resin material with the semiconductor chip being bonded to the lead frame;
removing the resin material in the groove portion by laser processing using the laser processing method according to claim 9; and
cutting the lead frame along the groove portion.
